(19) United States
(12) Patent Application Publication
(10) Pub. No.: US 2026/0153696 A1
(43) Pub. Date: Jun. 4, 2026

(54) PHOTONICS CHIP STRUCTURE AND SEMICONDUCTOR PACKAGE INCLUDING THE SAME

(71) Applicant: SAMSUNG ELECTRONICS CO., LTD., Suwon-si (KR)

(72) Inventors: Jing Cheng LIN, Suwon-si (KR); Jung Hua Chang, Suwon-si (KR)

(73) Assignee: SAMSUNG ELECTRONICS CO., LTD., Suwon-si (KR)

(21) Appl. No.: 19/357,804

(22) Filed: Oct. 14, 2025

(30) Foreign Application Priority Data
Dec. 3, 2024 (KR) 10-2024-0177913

(51) Int. Cl. G02B 6/42; H10W 90/00

(52) U.S. Cl. CPC G02B 6/4224; G02B 6/4206; G02B 6/4239; H10W 90/00

(57) ABSTRACT

A photonics chip structure may include: a photonics integrated circuit chip; an electronic integrated circuit chip on the photonics integrated circuit chip; an optical block on the photonics integrated circuit chip, and horizontally spaced apart from the electronic integrated circuit chip, the optical block including at least one microlens, and the optical block configured to provide a path of an optical signal of the photonics integrated circuit chip; and a frame on an upper surface of the optical block, the frame extending in a vertical direction on the upper surface of the optical block, and the frame configured to protect the at least one microlens.

### CROSS-REFERENCE TO RELATED APPLICATION

This application is based on and claims priority under 35 U.S.C. §119 to Korean Patent Application No. 10-2024-0177913, filed on December 3, 2024, in the Korean Intellectual Property Office, the disclosure of which is incorporated by reference herein in its entirety.

### BACKGROUND

### 1. Field

Some embodiments of the present disclosure relate to a photonics chip structure and a semiconductor package including the same, and more particularly, to a semiconductor package including a photonics chip structure including a photonics integrated circuit chip.

### 2. Description of Background Art

As the electronics industry advances rapidly and the demands of users increases, electronic devices are being miniaturized further and becoming more multifunctional. As electronic devices are miniaturized and made light, semiconductor packages are being miniaturized and made light, and moreover, semiconductor packages need a degree of high integration.

Therefore, semiconductor packages where various integrated circuits such as a memory chip and a logic chip are mounted on a package substrate are being developed to provide a multifunction. Particularly, in an environment where data traffic is increasing in data centers and communication infrastructure, research on semiconductor packages including a photonics integrated circuit is ongoing recently.

### SUMMARY

According to an embodiment of the present disclosure, a high-efficiency optical engine and a semiconductor package including the same may be provided.

According to an embodiment of the present disclosure, an optical engine, which is improved in consistency of a microlens and is improved in coupling efficiency, and a semiconductor package including the optical engine, may be provided.

According to an embodiment of the present disclosure, a photonics chip structure may be provided and include: a photonics integrated circuit chip; an electronic integrated circuit chip on the photonics integrated circuit chip; an optical block on the photonics integrated circuit chip, and horizontally spaced apart from the electronic integrated circuit chip, the optical block including at least one microlens, and the optical block configured to provide a path of an optical signal of the photonics integrated circuit chip; and a frame on an upper surface of the optical block, the frame extending in a vertical direction on the upper surface of the optical block, and the frame configured to protect the at least one microlens.

According to an embodiment of the present disclosure, a semiconductor package may be provided and include: a first package substrate; a second package substrate on the first package substrate; a semiconductor chip structure on the second package substrate; and a photonics chip structure horizontally spaced apart from the semiconductor chip structure, on the second package substrate, wherein the photonics chip structure includes: a photonics integrated circuit chip; an electronic integrated circuit chip on the photonics integrated circuit chip; an optical block on the photonics integrated circuit chip, and horizontally spaced apart from the electronic integrated circuit chip , the optical block including at least one microlens, and the optical block configured to provide a path of an optical signal of the photonics integrated circuit chip; and a frame on the optical block, the frame extending in a vertical direction on an upper surface of the optical block along an edge of the optical block, and the frame configured to protect the at least one microlens.

According to an embodiment of the present disclosure, a semiconductor package may be provided and include: a photonics interposer including a grating coupler; a semiconductor chip structure on the photonics interposer; an electronic integrated circuit chip horizontally spaced apart from the semiconductor chip structure, on the photonics interposer; an optical block on the photonics interposer, and horizontally spaced apart from the electronic integrated circuit chip , the optical block including a microlens, and the optical block configured to provide a path of an optical signal of the photonics interposer; and a frame on the optical block, the frame extending in a vertical direction on an upper surface of the optical block along an edge of the optical block, and the frame configured to protect the microlens.

Aspects of embodiments of the present disclosure are not limited to the above aspects, and other aspects not described above will be clearly understood by those of ordinary skill in the art from the description below.

### BRIEF DESCRIPTION OF DRAWINGS

Embodiments will be more clearly understood from the following detailed description taken in conjunction with the accompanying drawings in which:

FIG. 1 is a plan view schematically illustrating a semiconductor package according to an embodiment;

FIG. 2 is a cross-sectional view of the semiconductor package taken along a line I-I’ of FIG. 1;

FIG. 3 is a cross-sectional view of the semiconductor package taken along a line II-II’ of FIG. 1;

FIG. 4 is a cross-sectional view schematically illustrating a photonics chip structure according to an embodiment;

FIG. 5 is a perspective view schematically illustrating an optical block according to an embodiment;

FIG. 6 is a plan view schematically illustrating a positional relationship between a microlens and a grating coupler;

FIGS. 7A-H are plan views schematically illustrating shapes of an alignment mark according to embodiments;

FIG. 8 is a cross-sectional view schematically illustrating a photonics chip structure according to an embodiment;

FIG. 9 is a plan view schematically illustrating a semiconductor package according to an embodiment;

FIG. 10 is a cross-sectional view of the semiconductor package taken along a line III-III’ of FIG. 9; and

FIGS. 11 to 20 are diagrams schematically illustrating a process of a method of manufacturing the semiconductor package of FIG. 1, according to an embodiment.

### DETAILED DESCRIPTION

Hereinafter, non-limiting example embodiments will be described in detail with reference to the accompanying drawings. The same reference numerals are used for the same components in the drawings, and redundant descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

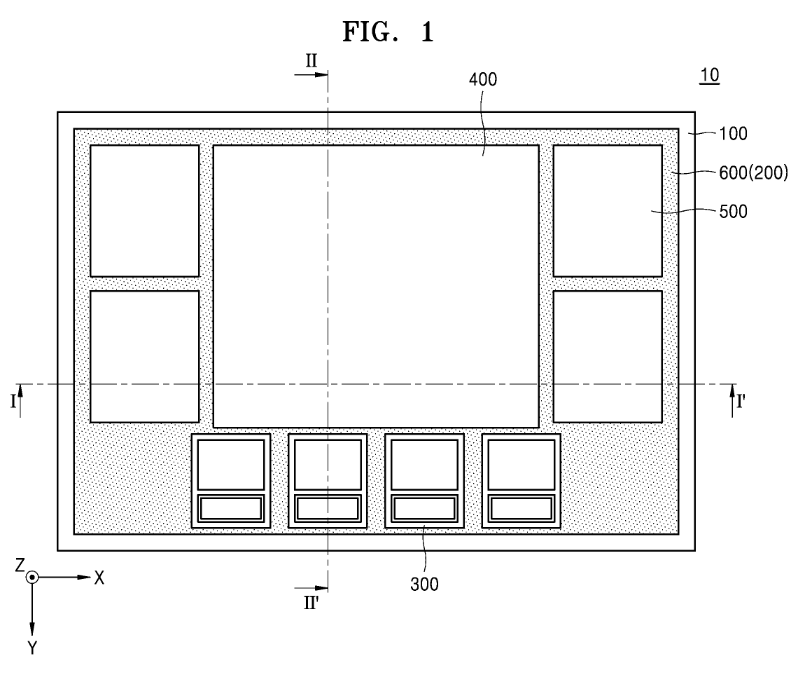

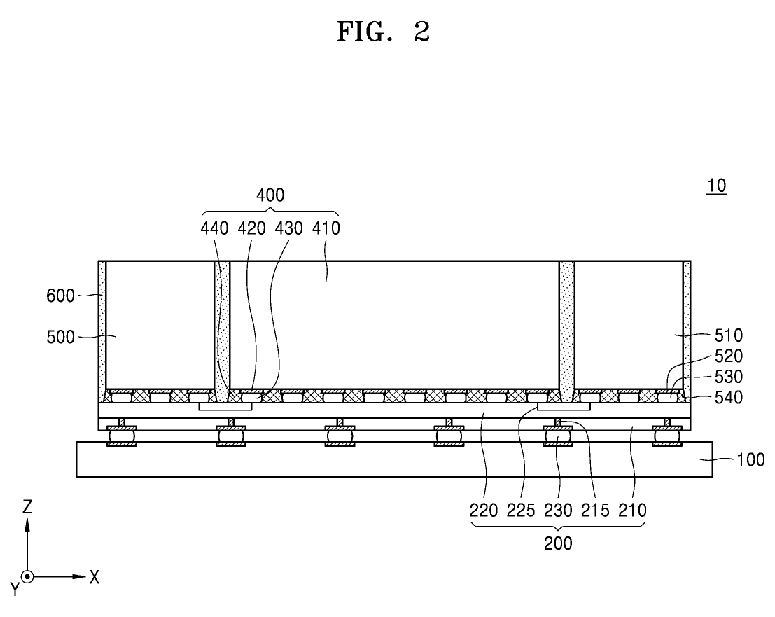

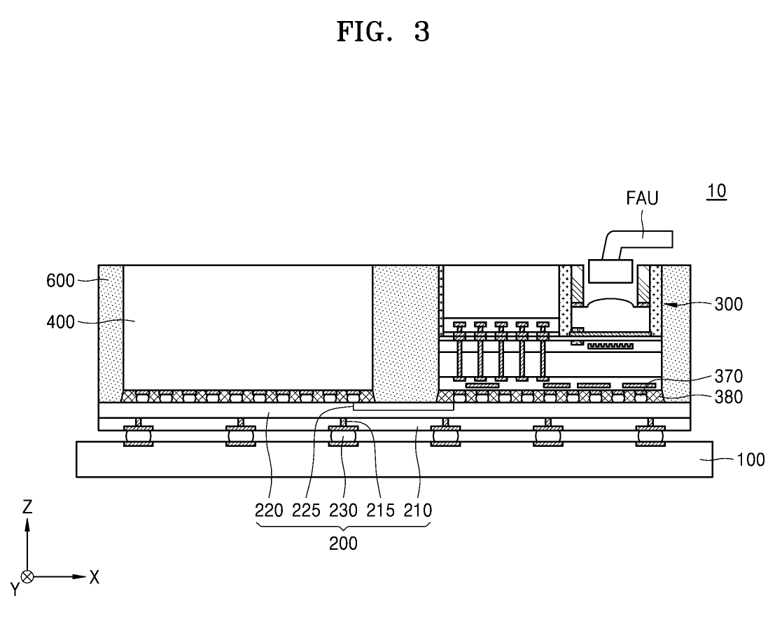

FIG. 1 is a plan view schematically illustrating a semiconductor package 10 according to an embodiment. FIG. 2 is a cross-sectional view of the semiconductor package 10 taken along a line I-I’ of FIG. 1. FIG. 3 is a cross-sectional view of the semiconductor package 10 taken along a line II-II’ of FIG. 1.

Referring to FIGS. 1 to 3, the semiconductor package 10 may include a first package substrate 100, a second package substrate 200, a photonics chip structure 300, a first chip structure 400, a second chip structure 500, and a package molding layer 600. According to embodiments, the semiconductor package 10 may be a semiconductor package which communicates with an external device by using an optical signal. In an embodiment, the semiconductor package 10 may be a semiconductor package including an optical engine.

Hereinafter, unless specially defined, a direction parallel to an upper surface of the first package substrate 100 may be defined as a first horizontal direction (e.g., an X direction), a direction perpendicular to the upper surface of the first package substrate 100 may be defined as a vertical direction (e.g., a Z direction), and a direction perpendicular to the first horizontal direction (e.g., the X direction) and the vertical direction (e.g., the Z direction) may be defined as a second horizontal direction (e.g., a Y direction).

The first package substrate 100 may be a substrate with the second package substrate 200 mounted thereon. In some embodiments, the first package substrate 100 may be a motherboard on which several kinds of semiconductor chips and packages are mounted. Moreover, in some embodiments, the first package substrate 100 may be a substrate which receives an electrical signal from the second package substrate 200 and transfers the electrical signal to an external device.

According to embodiments, the first package substrate 100 may be a printed circuit board (PCB), which includes a wiring pattern and an insulating layer surrounding the wiring pattern. In this case, the wiring pattern may include copper, nickel, stainless steel, or beryllium copper, and the insulating layer may include at least one material selected from among phenol resin, epoxy resin, and polyimide. The insulating layer may include, for example, at least one material selected from among frame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

The second package substrate 200 may be mounted on the first package substrate 100. The first chip structure 400, the second chip structure 500, and the photonics chip structure 300 may be mounted on an upper surface of the second package substrate 200. The second package substrate 200 may electrically connect the first chip structure 400, the second chip structure 500, and the photonics chip structure 300 with each other. Also, the second package substrate 200 may be electrically connected to the first package substrate 100 through at least one connection terminal 230 of the second package substrate 200. The second package substrate 200 may electrically connect the first chip structure 400, the second chip structure 500, and the photonics chip structure 300 to the first package substrate 100.

In some embodiments, the second package substrate 200 may be an interposer substrate. The second package substrate 200 may include a body layer 210 and a wiring layer 220. The wiring layer 220 may be disposed on an upper surface of the body layer 210. At least one through via 215 may be formed in the body layer 210. The through via 215 may pass through the body layer 210 in the vertical direction (e.g., the Z direction). According to embodiments, the through via 215 may include a through silicon via (TSV). The wiring layer 220 may include a wiring pattern 225. The wiring pattern 225 may electrically connect the first chip structure 400, the second chip structure 500, and the photonics chip structure 300 with each other, or may electrically connect the first chip structure 400 to the at least one through via 215, the second chip structure 500 to the at least one through via 215, and the photonics chip structure 300 to the at least one through via 215. The at least one through via 215 may be electrically connected to the first package substrate 100 through a pad and a bump each formed on a lower surface of the body layer 210.

The second package substrate 200 has been described as a silicon interposer including a TSV, but is not limited thereto and may also be a glass interposer including a through glass via (TGV).

Additionally, in some embodiments, the second package substrate 200 may be a redistribution structure including a redistribution pattern and a redistribution insulating layer surrounding the redistribution pattern. The redistribution insulating layer may include, for example, an insulating material (e.g., photo imageable dielectric (PID) resin). In some embodiments, the redistribution insulating layer may further include an inorganic filler. In some embodiments, the redistribution insulating layer may have a multi-layer structure where the redistribution pattern is disposed in each layer. The redistribution pattern may include a redistribution line pattern and a redistribution via pattern extending in the vertical direction (e.g., the Z direction) from the redistribution line pattern. The redistribution line pattern may be disposed on at least one from among an upper surface and a lower surface of the redistribution insulating layer, or may be disposed in the redistribution insulating layer. The redistribution via pattern may pass through the redistribution insulating layer and may be connected to a portion of the redistribution line pattern. The redistribution pattern may include a conductive material. For example, the redistribution pattern may include copper (Cu), aluminum (Al), silver (Ag), tin (Sn), gold (Au), nickel (Ni), lead (Pb), titanium (Ti), or a combination thereof.

The photonics chip structure 300, the first chip structure 400, and the second chip structure 500 may be mounted on the upper surface of the second package substrate 200. According to an embodiment, the photonics chip structure 300 may be disposed at an outer portion of the upper surface of the second package substrate 200.

In some embodiments, the first chip structure 400 may be disposed adjacent to a center portion of the upper surface of the second package substrate 200, and a plurality of the second chip structures 500 may be apart from the first chip structure 400 in the first horizontal direction (e.g., the X direction) and may be disposed at both sides of the first chip structure 400 in the first horizontal direction (e.g., the X direction). The photonics chip structure 300 may be disposed apart from the first chip structure 400 in the second horizontal direction (e.g., the Y direction).

In FIG. 1, the semiconductor package 10 is illustrated as including one first chip structure 400, four second chip structures 500, and four photonics chip structures 300, but the number of first chip structures 400, second chip structures 500, and photonics chip structures 300 included in the semiconductor package 10 is not limited thereto. Also, for example, the semiconductor package 10 may include only one of the first chip structure 400 and the second chip structure 500.

The first chip structure 400 may include a first chip body 410, first chip pad 420, and a first chip bump 430. Herein, the first chip structure 400 may be a non-memory chip structure including a non-memory device. The first chip body 410 may include, for example, silicon. Alternatively, the first chip body 410 may include a semiconductor element, such as germanium (Ge), or a compound semiconductor such as silicon carbide (SiC), gallium arsenide (GaAs), indium arsenide (InAs), or indium phosphide (InP). Alternatively, the first chip body 410 may have a silicon on insulator (SOI) structure. For example, the first chip body 410 may include a buried oxide (BOX) layer. The first chip body 410 may include a conductive region, for example, an impurity-doped well or an impurity-doped structure. Also, the first chip body 410 may have various device isolation structures such as a shallow trench isolation (STI) structure.

The first chip structure 400 may be, for example, a system on chip, a central processing unit (CPU) chip, a graphics processing unit (GPU) chip, or an application processor (AP) chip. The first chip structure 400 may execute applications supported by the semiconductor package 10 by using a memory device included in the second chip structure 500. For example, the first chip structure 400 may include at least one processor among a CPU, an AP, a GPU, a neural processing unit (NPU), a tensor processing unit (TPU), a vision processing unit (VPU), an image signal processor (ISP), and a digital signal processor (DSP), and may execute specific arithmetic operations.

According to an embodiment, a plurality of first chip pads 420 may be arranged in a horizontal direction (e.g., the X direction and/or the Y direction) on a lower surface of the first chip body 410. According to an embodiment, an upper surface of the first chip pad 420 and the lower surface of the first chip body 410 may be coplanar with each other, and the first chip pad 420 may contact the first chip bump 430. The first chip pad 420 may receive an electrical signal from the second chip structure 500 or the photonics chip structure 300 through the second package substrate 200, or may transfer an electrical signal to the second chip structure 500 or the photonics chip structure 300.

The first chip pad 420 may include, for example, a conductive material including Cu, Au, Ag, Ni, tungsten (W), Al, or a combination thereof. In some embodiments, the first chip pad 420 may further include a barrier material for preventing the conductive material from being diffused to the outside of the first chip pad 420. The barrier material may include, for example, titanium (Ti), tantalum (Ta), titanium nitride (TiN), tantalum nitride (TaN), or a combination thereof.

According to an embodiment, a plurality of first chip bumps 430 may be respectively attached to a plurality of first chip pads 420 of the first chip body 410. The first chip bump 430 may include, for example, a conductive material including Sn, Pb, Ag, Cu, or a combination thereof. The first chip bump 430 may include, for example, a solder ball. The first chip bump 430 may connect the first chip structure 400 to the second package substrate 200.

According to embodiments, a first under-fill material layer 440 may be further disposed on the lower surface of the first chip body 410. The first under-fill material layer 440 may be disposed to surround the first chip bump 430, between the second package substrate 200 and the first chip structure 400. For example, the first under-fill material layer 440 may be formed by one from among a capillary under-fill process, a no-flow under-fill process, a molded under-fill process, and a non-conductive film process. The first under-fill material layer 440 may have a tapered shape where a horizontal width thereof decreases in the vertical direction (e.g., the Z direction) toward the first chip body 410 from the second package substrate 200.

The second chip structure 500 may include a second chip body 510, a second chip pad 520, and a second chip bump 530. Herein, the second chip structure 500 may be a memory chip structure including a memory device. The second chip body 510 may include, for example, silicon (Si). Alternatively, the second chip body 510 may include a semiconductor element, such as Ge, or a compound semiconductor such as SiC, GaAs, InAs, or InP. Alternatively, the second chip body 510 may have an SOI structure. For example, the second chip body 510 may include a BOX layer. The second chip body 510 may include a conductive region such as, for example, an impurity-doped well or an impurity-doped structure. Also, the second chip body 510 may have various device isolation structures such as an STI structure.

The second chip structure 500 may be, for example, dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM). According to an embodiment, the second chip structure 500 may include a memory cell chip including a cell of high bandwidth memory (HBM) DRAM.

According to an embodiment, a plurality of second chip pads 520 may be arranged in a lateral direction (e.g., the X direction and/or the Y direction) on a lower surface of the second chip body 510. According to an embodiment, an upper surface of the second chip pad 520 and the lower surface of the second chip body 510 may be coplanar with each other, and the second chip pad 520 may contact the second chip bump 530. The second chip pad 520 may receive an electrical signal from the first chip structure 400 or the photonics chip structure 300 through the second package substrate 200, or may transfer an electrical signal to the first chip structure 400 or the photonics chip structure 300.

The second chip pad 520 may include, for example, a conductive material including Cu, Au, Ag, Ni, W, Al, or a combination thereof. In some embodiments, the second chip pad 520 may further include a barrier material for preventing the conductive material from being diffused to the outside of the first chip pad 420. The barrier material may include, for example, Ti, Ta, TiN, TaN, or a combination thereof.

According to an embodiment, a plurality of second chip bumps 530 may be respectively attached to a plurality of second chip pads 520 of the second chip body 510. The second chip bump 530 may include, for example, a conductive material including Sn, Pb, Ag, Cu, or a combination thereof. The second chip bump 530 may include, for example, a solder ball. The second chip bump 530 may connect the second chip structure 500 to the second package substrate 200.

According to embodiments, a second under-fill material layer 540 may be further disposed on the lower surface of the second chip body 510. The second under-fill material layer 540 may be disposed to surround the second chip bump 530, between the second package substrate 200 and the second chip structure 500. For example, the second under-fill material layer 540 may be formed by one from among a capillary under-fill process, a no-flow under-fill process, a molded under-fill process, and a non-conductive film process. The second under-fill material layer 540 may have a tapered shape where a horizontal width thereof decreases in the vertical direction (e.g., the Z direction) toward the second chip body 510 from the second package substrate 200.

It has been described that the first chip structure 400 may be a non-memory chip structure and the second chip structure 500 may be a memory chip structure, but embodiments of the present disclosure are not limited thereto. In some embodiments, the first chip structure 400 may be a memory chip structure including a memory chip, and the second chip structure 500 may be a non-memory chip structure including a non-memory device.

The photonics chip structure 300 may be apart from the first chip structure 400 and the second chip structure 500 in a horizontal direction (e.g., the X direction and/or the Y direction) and may be mounted on the second package substrate 200. In some embodiments, the photonics chip structure 300 may be mounted on the second package substrate 200 via at least one connection terminal 370 such as a micro-bump, based on a flip chip type. According to embodiments, an under-fill material layer 380 surrounding the connection terminal 370 may be disposed between the photonics chip structure 300 and the second package substrate 200. The under-fill material layer 380 may have substantially the same configuration as the first under-fill material layer 440 and the second under-fill material layer 540 described above with respect to the the first chip structure 400 and the second chip structure 500.

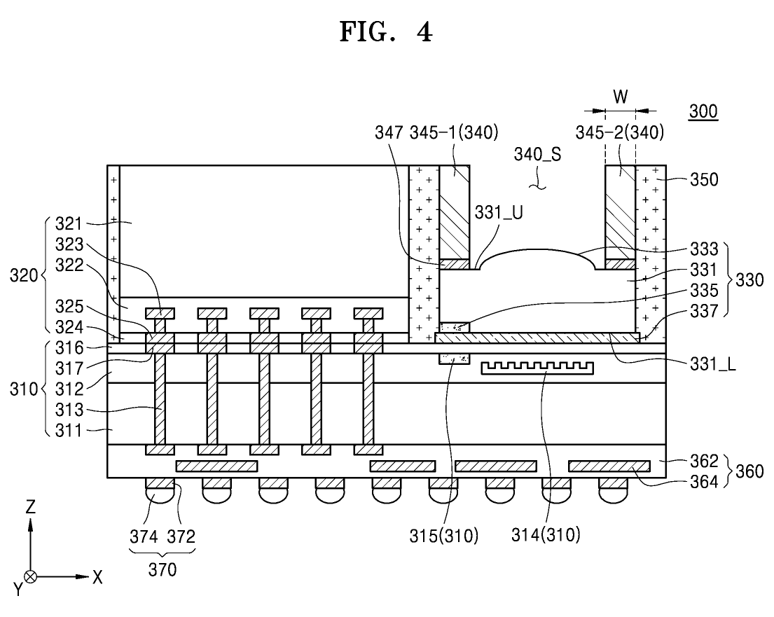

The semiconductor package 10 may communicate with an external device through the photonics chip structure 300 by using an optical signal. The photonics chip structure 300 may receive an optical signal from an external device, may convert the received optical signal into an electrical signal, and may input the electrical signal to the first chip structure 400 or the second chip structure 500 through the second package substrate 200. Here, the photonics chip structure 300 may be understood as an optical engine. The photonics chip structure 300 will be described below in detail with reference to FIG. 4.

The package molding layer 600 may be formed on an upper surface of the second package substrate 200 to surround the first chip structure 400, the second chip structure 500, and the photonics chip structure 300. In some embodiments, the package molding layer 600 may cover a side surface of each of the first chip structure 400, the second chip structure 500, and the photonics chip structure 300, and may not cover an upper surface of each of the first chip structure 400, the second chip structure 500, and the photonics chip structure 300. In this case, an upper surface of the package molding layer 600 and the upper surface of each of the first chip structure 400, the second chip structure 500, and the photonics chip structure 300 may be coplanar with respect to each other. In the same sense, the upper surface of the package molding layer 600 and the upper surface of each of the first chip structure 400, the second chip structure 500, and the photonics chip structure 300 may have the same vertical level.

According to embodiments, the package molding layer 600 may include thermocurable resin such as epoxy resin, thermoplastic resin such as polyimide, or resin including a reinforcing agent such as an inorganic filler, and in detail, may include Ajinomoto build-up film (ABF), FR-4, or BT, but is not limited thereto and the package molding layer 600 may include a molding material, such as epoxy mold compound (EMC), or a photosensitive material such as photoimagable encapsulant (PIE). In some embodiments, a portion of the package molding layer 600 may include an insulating material such as silicon oxide, silicon nitride, or silicon oxynitride.

In some embodiments, the package molding layer 600 may fill a gap between the first chip structure 400, the second chip structure 500, and the photonics chip structure 300 and the second package substrate 200 through a molded under-fill process. In this case, each of the first under-fill material layer 440, the second under-fill material layer 540, and the under-fill material layer 380 may be omitted.

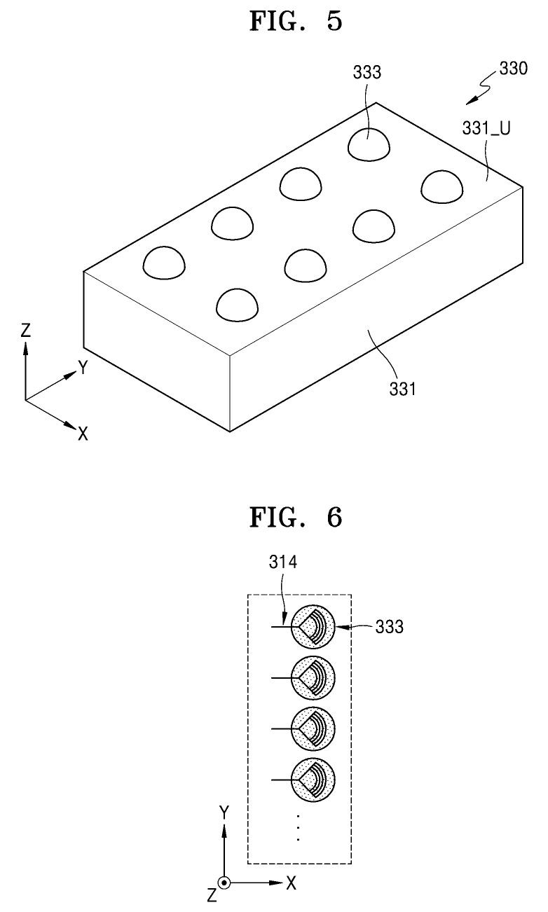

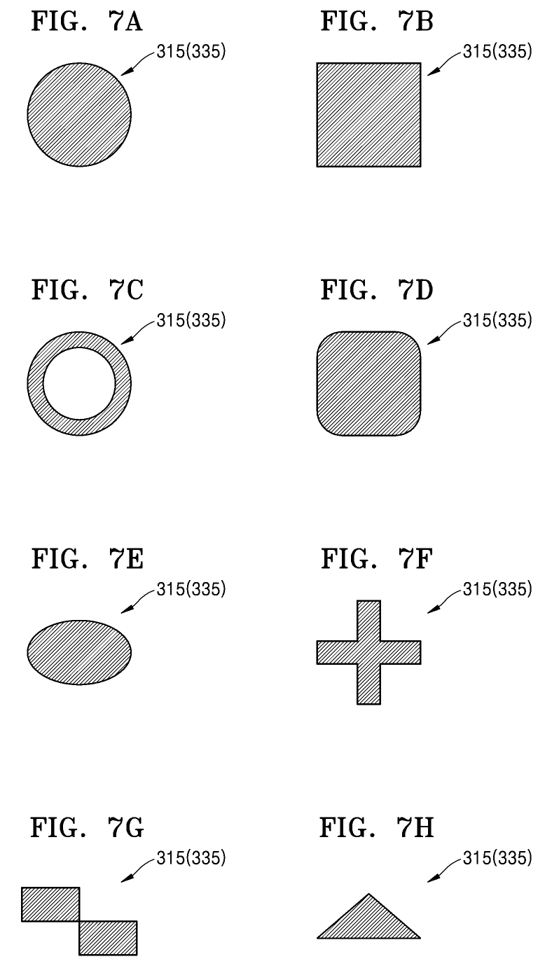

FIG. 4 is a cross-sectional view schematically illustrating a photonics chip structure 300 according to an embodiment. FIG. 5 is a perspective view schematically illustrating an optical block 330 according to an embodiment. FIG. 6 is a plan view schematically illustrating a position relationship between a microlens and a grating coupler. FIGS. 7A-7H are plan views schematically illustrating shapes of an alignment mark according to embodiments.

Referring to FIG. 4, the photonics chip structure 300 may include a photonics integrated circuit chip 310, an electronic integrated circuit chip 320, the optical block 330, a frame 340, a molding layer 350, a redistribution structure 360, and a connection terminal 370. The photonics chip structure 300 illustrated in FIG. 4 may be an embodiment of the photonics chip structure 300 illustrated in FIGS. 1 and 3.

According to an embodiment, the photonics integrated circuit chip 310 may include a first substrate 311, a first interlayer insulating layer 312, a through via 313, a grating coupler 314, a first alignment mark 315, a first passivation layer 316, and a first connection pad 317.

The first substrate 311 may include a semiconductor material such as Si or Ge. The first substrate 311 may include an upper surface and a lower surface opposite thereto. Here, the lower surface of the first substrate 311 may be a surface facing the redistribution structure 360. The through via 313 may pass through the first substrate 311 and may extend from the upper surface of the first substrate 311 to the lower surface of the first substrate 311. A lower end of the through via 313 may be electrically connected to the redistribution structure 360 in contact with a connection pad.

The first interlayer insulating layer 312 may be disposed on an upper surface of the first substrate 311. For example, the first interlayer insulating layer 312 may have a uniform thickness and be formed along the upper surface of the first substrate 311. According to some embodiments, the first interlayer insulating layer 312 may include an inorganic insulating layer such as silicon oxide (SiO) or silicon nitride (SiN). Alternatively, the first interlayer insulating layer 312 may include a polymer material. Alternatively, the first interlayer insulating layer 312 may include a dielectric polymer or a photoimageable dielectric (PID). For example, the PID may include at least one from among polyimide, polybenzoxazole (PBO), a phenol-based polymer, and a benzocyclobutene-based polymer. The first interlayer insulating layer 312 may include two or more insulating materials which are stacked mutually.

The through via 313 may be formed to pass through the first substrate 311 and the first interlayer insulating layer 312. In detail, the through via 313 may extend to the first connection pad 317 from the lower surface of the first substrate 311.

The through via 313 may include, for example, a conductive material including Cu, Au, Ag, Ni, W, Al, or a combination thereof. In some embodiments, the through via 313 may further include a barrier material for preventing the conductive material from being diffused to the outside of the through via 313. The barrier material may include, for example, Ti, Ta, TiN, TaN, or a combination thereof.

In FIG. 4, it is illustrated that the through via 313 passes through the first interlayer insulating layer 312 and is connected to the first connection pad 317, but embodiments of the present disclosure are not limited thereto, and the through via 313 may pass through only the first substrate 311 and may be connected to the first interlayer insulating layer 312. In this case, the first interlayer insulating layer 312 may further include a wiring pattern. For example, the wiring pattern may include a wiring line extending in a horizontal direction (e.g., the X direction and/or the Y direction) and a wiring via which vertically connects wiring lines with each other and may electrically connect the through via 313 to the first connection pad 317.

The grating coupler 314 may be buried in the first interlayer insulating layer 312. The grating coupler 314 may be configured to couple an optical signal input to the optical block 330 through an optical fiber unit FAU. In detail, an optical signal transferred to the grating coupler 314 through the optical block 330 may be coupled to another waveguide. According to an embodiment, a waveguide and an optical component may be disposed in the first interlayer insulating layer 312, and the grating coupler 314 may be disposed in one region of the waveguide. The waveguide may be a patterned silicon layer and may extend in a first horizontal direction (e.g., the X direction). In some embodiments, the waveguide may be a waveguide including silicon, and the first interlayer insulating layer 312 may be a BOX layer. However, embodiments of the present disclosure are not limited thereto, and the waveguide may be covered by an oxide layer distinguished from the first interlayer insulating layer 312. The optical component may be connected to the waveguide and may convert an optical signal into an electrical signal or may convert an electrical signal into an optical signal. The optical component may include a photodetector, a photodiode, and a modulator.

The grating coupler 314 may be disposed to be aligned with the optical block 330. For example, the grating coupler 314 may be disposed in the first interlayer insulating layer 312 to vertically overlap with the optical block 330. In FIG. 4, one grating coupler 314 is illustrated, but embodiments of the present disclosure are not limited thereto, and a plurality of grating couplers 314 may be provided based on an optical fiber unit FAU and a microlens 333 of the optical block 330. A position relationship between the microlens 333 and the grating coupler 314 will be described below along with a structure of the optical block 330.

The first alignment mark 315 may be disposed in the first interlayer insulating layer 312. According to an embodiment, in the first interlayer insulating layer 312, the first alignment mark 315 may be disposed so that an upper surface of the first alignment mark 315 is at the same vertical level as an upper surface of the first interlayer insulating layer 312. Also, in a horizontal viewpoint, the first alignment mark 315 may be disposed close to one side of the first interlayer insulating layer 312. For example, the electronic integrated circuit chip 320 and the optical block 330 may be horizontally apart from each other on the photonics integrated circuit chip 310, and the first alignment mark 315 may be disposed close to one side to vertically overlap with the optical block 330.

The first alignment mark 315 may perform guidance so that the optical block 330 is disposed at an appropriate position on the photonics integrated circuit chip 310. For example, the optical block 330 may be disposed on the photonics integrated circuit chip 310 so that the first alignment mark 315 is aligned with a second alignment mark 335.

According to an embodiment, as illustrated in FIGS. 7A-7H, the first alignment mark 315 may have a shape such as a circular shape, a circular ring shape, an oval shape, a tetragonal shape, a round tetragonal shape, a “+”-shape, or a triangular shape. The first alignment mark 315 may have a shape corresponding to the second alignment mark 335. According to an embodiment, the first alignment mark 315 may include metal such as, for example, Cu.

The first passivation layer 316 may be disposed on the first interlayer insulating layer 312. The first passivation layer 316 may protect the first interlayer insulating layer 312 and a lower structure. The first passivation layer 316 may include an insulating material such as, for example, silicon carbonitride (SiCN).

The first connection pad 317 may be disposed on the first interlayer insulating layer 312. For example, the first connection pad 317 may be buried in the first passivation layer 316, and a side surface of the first connection pad 317 may be surrounded by the first passivation layer 316. Also, an upper surface of the first connection pad 317 may not be covered by the first passivation layer 316. The upper surface of the first connection pad 317 may be disposed at the same vertical level as an upper surface of the first passivation layer 316. The first connection pad 317 may be electrically connected to the through via 313 and may be bonded to a second connection pad 325 of the electronic integrated circuit chip 320.

According to an embodiment, the electronic integrated circuit chip 320 may be mounted on the photonics integrated circuit chip 310. The electronic integrated circuit chip 320 may be disposed on the photonics integrated circuit chip 310 and may be disposed apart from the optical block 330 in the horizontal direction (e.g., the X direction and/or the Y direction). The electronic integrated circuit chip 320 may be configured to interconnect the photonics integrated circuit chip 310 with chip structures (e.g., the first chip structure 400 and the second chip structure 500). For example, the electronic integrated circuit chip 320 may convert an electrical signal obtained through conversion by the photonics integrated circuit chip 310 to match the chip structures (e.g., the first chip structure 400 and the second chip structure 500).

In some embodiments, a horizontal width of the electronic integrated circuit chip 320 may be less than a width of the photonics integrated circuit chip 310. A footprint of the electronic integrated circuit chip 320 may be less than a footprint of the photonics integrated circuit chip 310.

The electronic integrated circuit chip 320 may include a second substrate 321, a second interlayer insulating layer 322, a wiring structure 323, a second passivation layer 324, and the second connection pad 325.

The second substrate 321 may include a semiconductor material such as Si or Ge. The second substrate 321 may include an active surface and an inactive surface opposite thereto. In some embodiments, the electronic integrated circuit chip 320 may include a plurality of individual elements which are used in interfacing with the photonics integrated circuit chip 310. The plurality of individual elements of the electronic integrated circuit chip 320 may be disposed on the active surface of the second substrate 321. Here, the active surface of the second substrate 321 may be a lower surface of the second substrate 321. For example, the electronic integrated circuit chip 320 may include complementary metal oxide semiconductor (CMOS) drivers and transimpedance amplifiers so as to perform functions such as controlling high frequency signaling of the photonics integrated circuit chip 310.

According to an embodiment, the second interlayer insulating layer 322 may be disposed on the lower surface (“lower” in FIG. 4) of the second substrate 321. For example, the second interlayer insulating layer 322 may have a uniform thickness and be formed along the lower surface of the second substrate 321. According to some embodiments, the second interlayer insulating layer 322 may include an inorganic insulating layer such as SiO or SiN. Alternatively, the second interlayer insulating layer 322 may include a polymer material. Alternatively, the second interlayer insulating layer 322 may include a dielectric polymer or a PID. For example, the PID may include at least one from polyimide, PBO, a phenol-based polymer, and a benzocyclobutene-based polymer. The second interlayer insulating layer 322 may include two or more insulating materials which are stacked mutually.

The wiring structure 323 may be disposed in the second interlayer insulating layer 322. The wiring structure 323 may be connected to an individual element disposed on the active surface of the second substrate 321. Also, the wiring structure 323 may be electrically connected to the second connection pad 325. According to an embodiment, the wiring structure 323 may include a wiring line extending in a horizontal direction (e.g., the X direction and/or the Y direction) and a wiring via which vertically connects wiring lines with each other and may electrically connect the individual element to the second connection pad 325.

The second passivation layer 324 may be disposed on the second interlayer insulating layer 322. The second passivation layer 324 may protect the second interlayer insulating layer 322 and the wiring structure 323. The second passivation layer 324 may include an insulating material, for example, SiCN.

The second connection pad 325 may be disposed on the second interlayer insulating layer 322. For example, the second connection pad 325 may be buried in the second passivation layer 324, and a side surface of the second connection pad 325 may be surrounded by the second passivation layer 324. Also, an upper surface of the second connection pad 325 may not be covered by the second passivation layer 324. The lower surface of the second connection pad 325 may be disposed at the same vertical level as a lower surface of the second passivation layer 324. The second connection pad 325 may be electrically connected to the wiring structure 323 and may be bonded to the first connection pad 317 of the photonics integrated circuit chip 310.

In embodiments, the electronic integrated circuit chip 320 may be bonded to the photonics integrated circuit chip 310 by direct bonding. The direct bonding may include dielectric-to-dielectric bonding, copper-to-copper bonding, and hybrid bonding where the dielectric-to-dielectric bonding and the copper-to-copper bonding are performed together. In this case, the first connection pad 317 may be bonded to the second connection pad 325 through diffusion bonding based on heat. However, embodiments of the present disclosure are not limited thereto, and the electronic integrated circuit chip 320 may be electrically connected to the photonics integrated circuit chip 310 by a connection terminal, such as a solder ball, or an adhesive film such as a anisotropic film (ACF) or a non-conductive film (NCF).

The optical block 330 may be disposed on the photonics integrated circuit chip 310. For example, the optical block 330 may be apart from the electronic integrated circuit chip 320 in the first horizontal direction (e.g., the X direction) and may be disposed on the photonics integrated circuit chip 310. The optical block 330 may be disposed above the grating coupler 314 of the photonics integrated circuit chip 310. A horizontal width of the optical block 330 may be less than a horizontal width of the photonics integrated circuit chip 310.

The optical block 330 may include a body part 331, the microlens 333, and the second alignment mark 335.

The optical block 330 may include the body part 331 having a uniform refractive index. For example, a material of the body part 331 may include silicon, glass, or a polymer. An optical path, through which an external optical signal is transferred to the photonics integrated circuit chip 310, may be formed in the body part 331. The body part 331 of the optical block 330 may have a uniform refractive index, and thus, may decrease the reflection of light occurring between two materials having different refractive indexes while an optical signal is passing through the body part 331.

The optical block 330 may include the microlens 333. In an embodiment, the microlens 333 may be formed through a nano imprint process. For example, a mold where a pattern of a microlens is engraved may be manufactured, and then, a polymer or a photosensitive resist may be coated on a surface of a substrate including a material such as glass. Subsequently, the shape of the microlens may be transferred by pressing the mold, where the pattern of the microlens is engraved, on the substrate, and by performing annealing, washing, and coating, the optical block 330 including the microlens 333 may be formed. That is, in the optical block 330, the body part 331 and the microlens 333 may be provided as one body.

The microlens 333 may be formed on a body part upper surface 331_U. The microlens 333 may be formed in plural in one row or in a plurality of rows on the body part upper surface 331_U. For example, as illustrated in FIG. 5, the microlens 333 may be arranged in a plurality of rows in the first horizontal direction (e.g., the X direction) and a second horizontal direction (e.g., the Y direction). Alternatively, the microlens 333 may be arranged in one row in the second horizontal direction (e.g., the Y direction).

The microlens 333 may be disposed to correspond to the grating coupler 314. Referring to FIGS. 4 and 6, in the photonics chip structure 300 according to various embodiments, the microlens 333 and the grating coupler 314 may be provided as an array and may correspond to each other. A plurality of microlenses 333 may respectively correspond to a plurality of grating couplers 314. In detail, each of the plurality of microlenses 333 may overlap with a corresponding grating coupler 314 among the plurality of grating couplers 314 in a vertical direction (e.g., a Z direction). For example, as seen in a plane, when the plurality of grating couplers 314 include a 1x20 array or a 2x20 array, the plurality of microlenses 333 may also include a 1x20 array or a 2x20 array, based thereon.

An optical fiber unit FAU (see FIG. 3) may be disposed above the optical block 330. In detail, the optical fiber unit FAU may be disposed above the optical block 330 in alignment with the microlens 333. An external optical signal may enter the optical block 330 through an optical fiber of the optical fiber unit FAU. The optical fiber unit FAU may be a unit including a plurality of optical fibers. According to an embodiment, optical signals having different wavelengths may be respectively input or output to or from the optical fibers. In some embodiments, an optical signal having a multi-wavelength may be input or output to or from the optical fiber. For example, an optical signal emitted from the optical fiber may have a plurality of peak wavelengths.

The second alignment mark 335 may be disposed in the body part 331. According to an embodiment, the second alignment mark 335 may be disposed so that a lower surface of the second alignment mark 335 is at the same vertical level as a body part lower surface 331_L of the body part 331. The second alignment mark 335 may perform guidance so that the optical block 330 is disposed at an appropriate position on the photonics integrated circuit chip 310. For example, the optical block 330 may be disposed on the photonics integrated circuit chip 310 so that the second alignment mark 335 is aligned with the first alignment mark 315.

According to an embodiment, as illustrated in FIG. 7, the second alignment mark 335 may have a shape such as a circular shape, a circular ring shape, an oval shape, a tetragonal shape, a round tetragonal shape, a “+”-shape, or a triangular shape. The second alignment mark 335 may have a shape corresponding to the first alignment mark 315. According to an embodiment, the second alignment mark 335 may include metal, for example, Cu.

An optical adhesive layer 337 may be provided on the lower surface 331_L of the body part 331 of the optical block 330. The optical block 330 may be adhered to the photonics integrated circuit chip 310 with the optical adhesive layer 337 between the body part 331 and the photonics integrated circuit chip 310. The optical adhesive layer 337 may be provided at a position aligned (e.g., overlapping with) with the grating coupler 314 of the photonics integrated circuit chip 310 and may attach the optical block 330 to the photonics integrated circuit chip 310 so that an optical signal passing through the optical block 330 is transferred to the grating coupler 314.

The frame 340 may be disposed on the optical block 330. The frame 340 may be configured to protect the optical block 330 in the middle of and after a process of manufacturing the photonics chip structure 300.

The frame 340 may be formed to extend in the vertical direction (e.g., the Z direction) along an edge of the optical block 330, on the optical block 330. In detail, the frame 340 may include frame sidewalls (e.g., frame sidewalls 345-1 and 345-2), which may be formed along an edge of the optical block 330. Each of the plurality of frame sidewalls (e.g., frame sidewalls 345-1 and 345-2) may be connected to a frame sidewall adjacent thereto. In embodiments, a width w of each frame sidewall (e.g., frame sidewalls 345-1 and 345-2) may be formed to about 100 μm to about 5,000 μm. The frame 340 may be formed to extend in the vertical direction (e.g., the Z direction) on the upper surface of the optical block 330. In embodiments, an upper surface of the frame 340 may be disposed at the same vertical level as an upper surface of the electronic integrated circuit chip 320.

A frame inner space 340_S may be formed in an inner portion surrounded by the frame sidewalls (e.g., frame sidewalls 345-1 and 345-2). The microlens 333 and a portion of the optical fiber unit FAU may be disposed in the frame inner space 340_S. The frame 340 may protect the microlens 333 disposed in the frame inner space 340_S in the middle of a process of manufacturing the photonics chip structure 300.

The frame 340 may be attached to the body part upper surface 331_U of the optical block 330 via a frame adhesive layer 347. The frame 340 may be disposed on the body part upper surface 331_U of the optical block 330, and thus, a gap may not occur in a case where the frame 340 and the optical block 330 are disposed apart from each other. Accordingly, a problem where particles are caught in a gap or a bobble of an adhesive layer or a polymer occurs may be solved.

The molding layer 350 may seal the electronic integrated circuit chip 320 and the optical block 330, on the photonics integrated circuit chip 310. The molding layer 350 may cover an upper surface of the first passivation layer 316 of the photonics integrated circuit chip 310 and may surround a side surface of the electronic integrated circuit chip 320, a side surface of the optical block 330, and an outer surface of the frame 340. The molding layer 350 may not be disposed in the frame inner space 340_S. That is, the molding layer 350 may not fill the frame inner space 340_S surrounded by the frame sidewalls (e.g., frame sidewalls 345-1 and 345-2), and in the frame inner space 340_S, the optical fiber unit FAU may be disposed above the microlens 333 of the optical block 330. According to an embodiment, an upper surface of the molding layer 350 may be disposed at the same vertical level as the upper surface of the electronic integrated circuit chip 320 and the upper surface of the frame 340.

The molding layer 350 may include, for example, thermocurable resin such as epoxy resin, thermoplastic resin such as polyimide, or resin including an inorganic filler, and in detail, may include ABF, FR-4, BT, or resin. Also, a molding material such as EMC or a photosensitive material such as PIE may be used.

The redistribution structure 360 may be disposed under the photonics integrated circuit chip 310. The redistribution structure 360 may be a structure which electrically connects the photonics integrated circuit chip 310 to the second package substrate 200 (see FIG. 3). The redistribution structure 360 may be provided on the wiring layer 220 of the second package substrate 200. According to embodiments, the redistribution structure 360 may include a redistribution insulating layer 362 and a redistribution pattern 364. A plurality of the redistribution insulating layers 362 may be stacked in the vertical direction (the Z direction), and the redistribution pattern 364 may be provided in one or more of the redistribution insulating layers 362. The redistribution insulating layer 362 may be formed from PID or photosensitive polyimide (PSPI), and the redistribution pattern 364 may include metal, such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or an alloy of metals, but the inventive concept is not limited thereto. In some embodiments, the redistribution pattern 364 may be formed by stacking metal or an alloy of metals on a seed layer including copper, titanium, titanium nitride, or titanium tungsten. The photonics integrated circuit chip 310 and the second package substrate 200 may transfer and receive an electrically signal therebetween via the redistribution pattern 364 of the redistribution structure 360.

According to an embodiment, at least one connection terminal 370 may be disposed on a lower surface of the redistribution structure 360. The at least one connection terminal 370 may be a plurality of connection terminals 370 that respectively include chip pads 372, disposed from each other in the horizontal direction (e.g., the X direction and/or the Y direction) on the lower surface of the redistribution structure 360, and chip bumps 374 disposed on the chip pads 372.

The chip pad 372 may be disposed on the lower surface of the redistribution structure 360 and may provide a terminal where the chip bump 374 is to be disposed. In an embodiment, a material of the chip pad 372 may include Al. However, embodiments of the present disclosure are not limited to the above description, and a material of the chip pad 372 may include metal, such as Ni, Cu, Al, Au, Ag, W, Ti, Ta, In, Mo, Mn, Co, Sn, Mg, Re, Be, Ga, or Ru, or an alloy thereof.

The chip bump 374 may be a terminal for electrically connecting the photonics chip structure 300 to the second package substrate 200. In an embodiment, the chip bump 374 may be a solder of a metal material including at least one of Sn, Ag, Cu, and Al.

In the photonics chip structure 300 according to an embodiment, the microlens 333 may be formed in the optical block 330 by a nano imprint process, and thus, may newly include a microlens which was not previously provided in the photonics chip structure 300. Accordingly, the misalignment of a microlens may be prevented, and thus, the photonics chip structure 300 having enhanced coupling efficiency may be provided.

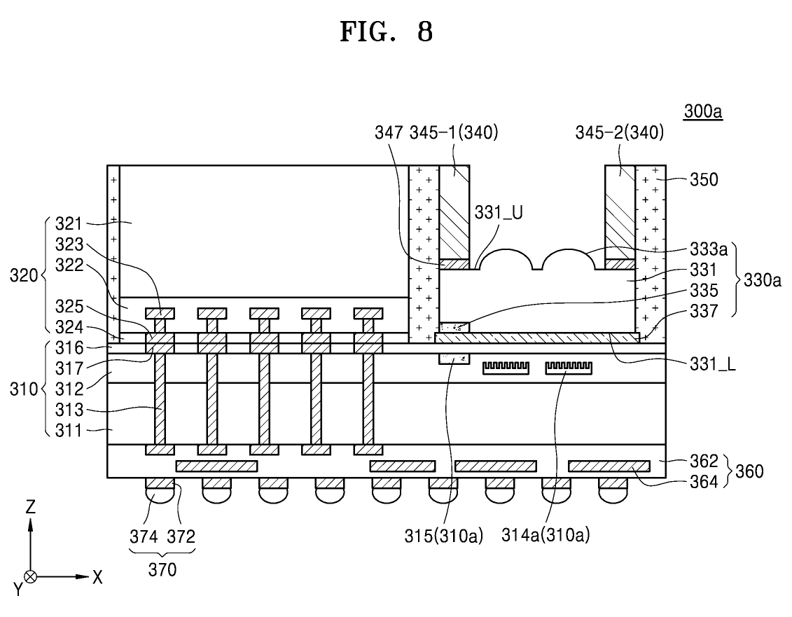

FIG. 8 is a cross-sectional view schematically illustrating a photonics chip structure 300a according to an embodiment. The photonics chip structure 300a described with reference to FIG. 8 may be an embodiment of the photonics chip structure 300 illustrated in FIGS. 1 and 3, and most elements configuring the photonics chip structure 300 and materials included in the elements may be the same as or similar to the elements and materials described with reference to FIG. 4. Therefore, for convenience of description, a difference between the photonics chip structure 300a of FIG. 8 and the photonics chip structure 300 of FIG. 4 may be mainly described.

Referring to FIG. 8, the photonics chip structure 300a according to an embodiment may include a photonics integrated circuit chip 310a, an electronic integrated circuit chip 320, an optical block 330a, a frame 340, a molding layer 350, a redistribution structure 360, and a connection terminal 370.

The optical block 330a may include a plurality of microlenses 333a. The microlens 333a and a body part 331 of the optical block 330a may be provided as one body. As described above with reference to FIG. 5, the microlens 333a may be provided in a plurality of rows. For example, the microlenses 333a may be provided in a plurality of rows in a first horizontal direction (e.g., the X direction) and, in each row, the microlenses 333 may be disposed apart from one another in a second horizontal direction (e.g., the Y direction). Each of the microlenses 333a may be connected to an optical fiber of an optical fiber unit FAU.

The photonics integrated circuit chip 310a may include a plurality of grating couplers 314a buried in a first interlayer insulating layer 312. Each of the grating couplers 314a may be disposed to be aligned in the microlens 333a of the optical block 330. In the photonics chip structure 300a of FIG. 8, the optical block 330a may include microlenses 333a of two rows, and thus, based thereon, grating couplers 314a of two rows may be disposed on a second interlayer insulating layer 322.

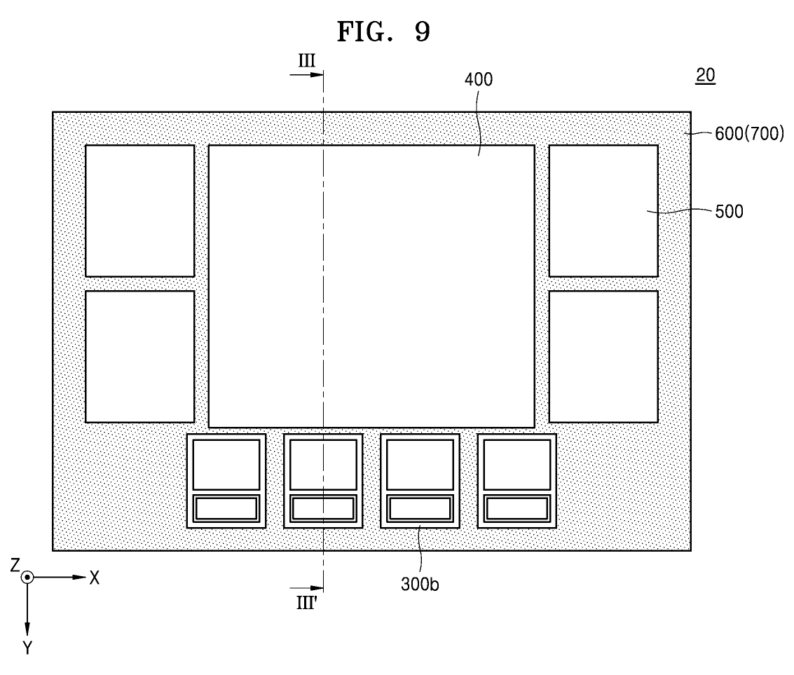

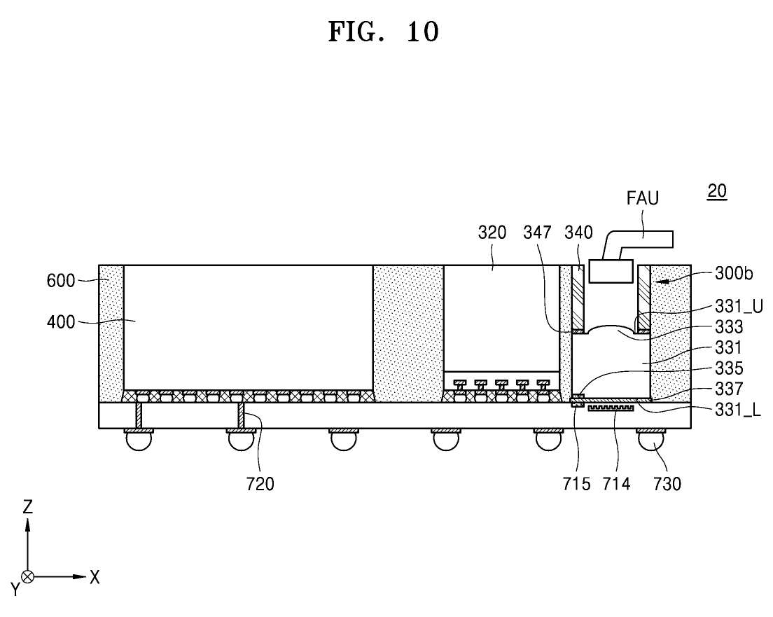

FIG. 9 is a plan view schematically illustrating a semiconductor package 20 according to an embodiment. FIG. 10 is a cross-sectional view of the semiconductor package 20 taken along a line III-III’ of FIG. 9. Most elements configuring the semiconductor package 20 described with reference to FIGS. 9 and 10 and materials included in the elements may be the same as or similar to the elements and materials described with reference to FIGS. 1-8. Therefore, for convenience of description, a difference with the semiconductor package 10 may be mainly described.

Referring to FIGS. 9 and 10, the semiconductor package 20 may include a photonics interposer 700, a photonics chip structure 300b, a first chip structure 400, a second chip structure 500, and a package molding layer 600. The semiconductor package 20 may be a semiconductor package which communicates with an external device by using an optical signal.

The first chip structure 400, the second chip structure 500, and the photonics chip structure 300b may be mounted on the photonics interposer 700. The first chip structure 400, the second chip structure 500, and the photonics chip structure 300b may be disposed apart from one another in a horizontal direction (e.g., the X direction and/or the Y direction) on the photonics interposer 700. The photonics interposer 700 may electrically connect the first chip structure 400, the second chip structure 500, and the photonics chip structure 300b with each other. Also, in some embodiments, the photonics interposer 700 may receive an electrical signal from the first chip structure 400, the second chip structure 500, and the photonics chip structure 300b and may transfer the electrical signal to an external device. In some embodiments, at least one through via 720 may be formed in the photonics interposer 700 and may be electrically connected to the first chip structure 400 and the second chip structure 500.

In some embodiments, the photonics interposer 700 may perform a function of a photonics integrated circuit chip 310 of the photonics chip structure 300 described above with reference to FIG. 4. A grating coupler 714 may be buried in the photonics interposer 700. The grating coupler 714 may be disposed to be aligned with the optical block 330. For example, the grating coupler 714 may be disposed in the photonics interposer 700 to vertically overlap with the optical block 330.

A first alignment mark 715 may be disposed in the photonics interposer 700. According to an embodiment, in a horizontal viewpoint, the first alignment mark 715 may be disposed close to one side of the photonics interposer 700. For example, the first alignment mark 715 may be disposed close to one side to vertically overlap the optical block 330 disposed on the photonics interposer 700.

The first alignment mark 315 may perform guidance so that the optical block 330 is disposed at an appropriate position on the photonics interposer 700. For example, the optical block 330 may be disposed on the photonics interposer 700 so that the first alignment mark 715 is aligned with a second alignment mark 335.

According to an embodiment, the electronic integrated circuit chip 320 may be mounted on the photonics interposer 700. The electronic integrated circuit chip 320 may be disposed on the photonics interposer 700 and may be disposed apart from the optical block 330 in the horizontal direction (e.g., the X direction and/or the Y direction).

The optical block 330 may be disposed on the photonics interposer 700. For example, the optical block 330 may be apart from the electronic integrated circuit chip 320 in the first horizontal direction (the X direction) and may be disposed on the photonics interposer 700. The optical block 330 may be disposed above the grating coupler 714 of the photonics interposer 700.

The optical block 330 may include a body part 331, a microlens 333, and the second alignment mark 335.

The optical block 330 may include the body part 331 having a uniform refractive index. An optical path, through which an external optical signal is transferred to the photonics interposer 700, may be formed in the body part 331.

The optical block 330 may include the microlens 333. In an embodiment, the microlens 333 may be formed through a nano imprint process. That is, in the optical block 330, the body part 331 and the microlens 333 may be provided as one body. The microlens 333 may be formed on a body part upper surface 331_U. The microlens 333 may be provided in a plural in one row or in a plurality of rows on the body part upper surface 331_U. The microlens 333 may be disposed to correspond to the grating coupler 714.

The second alignment mark 335 may be disposed in the body part 331. According to an embodiment, the second alignment mark 335 may be disposed so that a lower surface of the second alignment mark 335 is at the same vertical level as a body part lower surface 331_L of the body part 331. The second alignment mark 335 may perform guidance so that the optical block 330 is disposed at an appropriate position on the photonics interposer 700. For example, the optical block 330 may be disposed on the photonics interposer 700 so that the second alignment mark 335 is aligned with the first alignment mark 715.

An optical adhesive layer 337 may be provided on the lower surface 331_L of the body part 331 of the optical block 330. The optical block 330 may be adhered to the photonics interposer 700 with the optical adhesive layer 337 between the body part 331 and the photonics interposer 700. The optical adhesive layer 337 may be provided at a position aligned with the grating coupler 714 of the photonics interposer 700 and may attach the optical block 330 to the photonics interposer 700 so that an optical signal passing through the optical block 330 is transferred to the grating coupler 714.

The frame 340 may be disposed on the optical block 330. The frame 340 may be configured to protect the optical block 330 in the middle of and after a process of manufacturing the photonics chip structure 300. The frame 340 may be formed to extend in the vertical direction (e.g., the Z direction) along an edge of the optical block 330, on the optical block 330. The microlens 333 and a portion of the optical fiber unit FAU may be disposed in the frame inner space 340_S. The frame 340 may protect the microlens 333 disposed in the frame inner space 340_S in the middle of a process of manufacturing the photonics chip structure 300. The frame 340 may be attached to the body part upper surface 331_U of the optical block 330 via the frame adhesive layer 347.

The package molding layer 600 may be formed on an upper surface of the photonics interposer 700 to surround the first chip structure 400, the second chip structure 500, and the photonics chip structure 300b. In some embodiments, the package molding layer 600 may cover a side surface of each of the first chip structure 400, the second chip structure 500, and the photonics chip structure 300b and may not cover an upper surface of each of the first chip structure 400, the second chip structure 500, and the photonics chip structure 300b. In this case, an upper surface of the package molding layer 600 and the upper surface of each of the first chip structure 400, the second chip structure 500, and the photonics chip structure 300b may be coplanar with each other. In the same sense, the upper surface of the package molding layer 600 and the upper surface of each of the first chip structure 400, the second chip structure 500, and the photonics chip structure 300b may have the same vertical level.

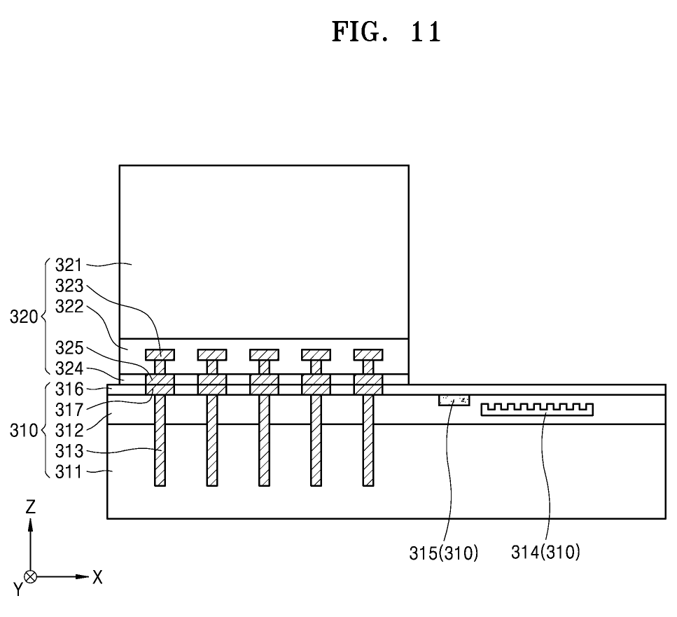

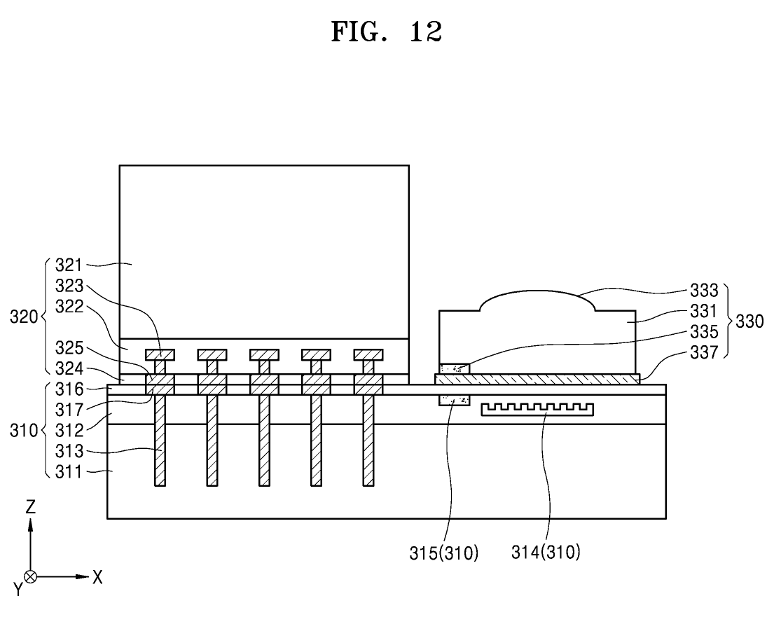

FIGS. 11-20 are diagrams schematically illustrating a process of a method of manufacturing the semiconductor package 10 of FIG. 1, according to an embodiment.

Referring to FIG. 11, a photonics integrated circuit chip 310 may be provided, and an electronic integrated circuit chip 320 may be attached to the photonics integrated circuit chip 310. The electronic integrated circuit chip 320 may be attached to the photonics integrated circuit chip 310 in a face-down manner so that an active surface of the electronic integrated circuit chip 320 and a wiring structure 323 face the photonics integrated circuit chip 310. The electronic integrated circuit chip 320 may be bonded to the photonics integrated circuit chip 310 so that a second connection pad 325 is bonded to a first connection pad 317 of the photonics integrated circuit chip 310.

In some embodiments, the electronic integrated circuit chip 320 may be bonded to the photonics integrated circuit chip 310 by hybrid bonding. In this case, the first connection pad 317 may be bonded to the second connection pad 325 through diffusion bonding based on heat.

Referring to FIG. 12, an optical block 330 may be attached to the photonics integrated circuit chip 310. The optical block 330 may be disposed on the photonics integrated circuit chip 310 so that a second alignment mark 335 is aligned with a first alignment mark 315. The optical block 330 may be adhered to the photonics integrated circuit chip 310 through an optical adhesive layer 337.

The optical block 330 may include a microlens 333, which is upward convex at an upper side of the optical block 330. The optical block 330 may be disposed such that the microlens 333 is aligned with a grating coupler 314 of the photonics integrated circuit chip 310. The microlens 333 may be formed through a nano imprint process, and the microlens 333 and the optical block 330 may be provided as one body. The microlens 333 may enhance the coupling efficiency of the grating coupler 314.

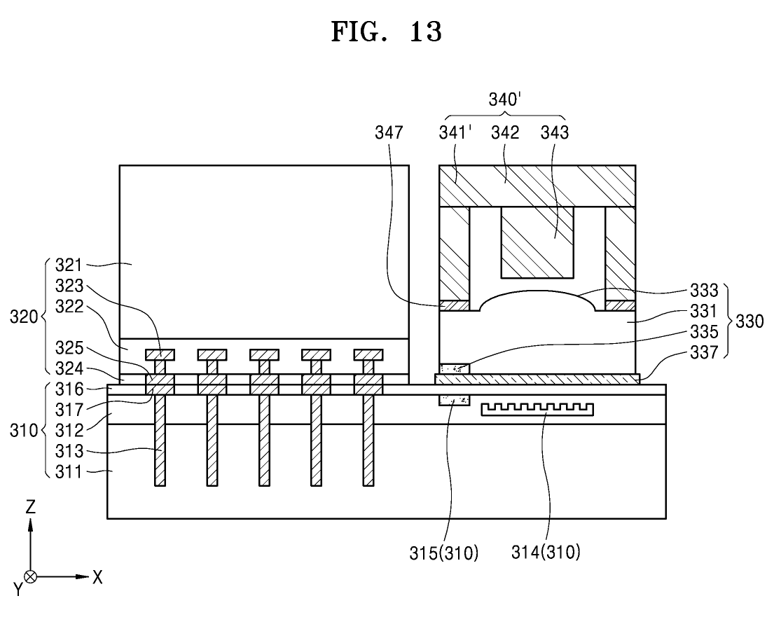

Referring to FIG. 13, a primary frame 340’ may be attached to the optical block 330. The primary frame 340’ may include a frame sidewall 341’, a frame upper portion 342, and an internal block 343. The primary frame 340’ may protect the microlens 333 of the optical block 330 in the middle of a process of manufacturing a photonics chip structure 300. Particularly, because the internal block 343 is provided, a thickness of the frame upper portion 342 may be maintained, and moreover, an internal gas volume of the primary frame 340’ may be reduced. Such a structure of the primary frame 340’ may be formed by grinding the primary frame 340’ by a thickness of the frame upper portion 342 and may thus be efficient.

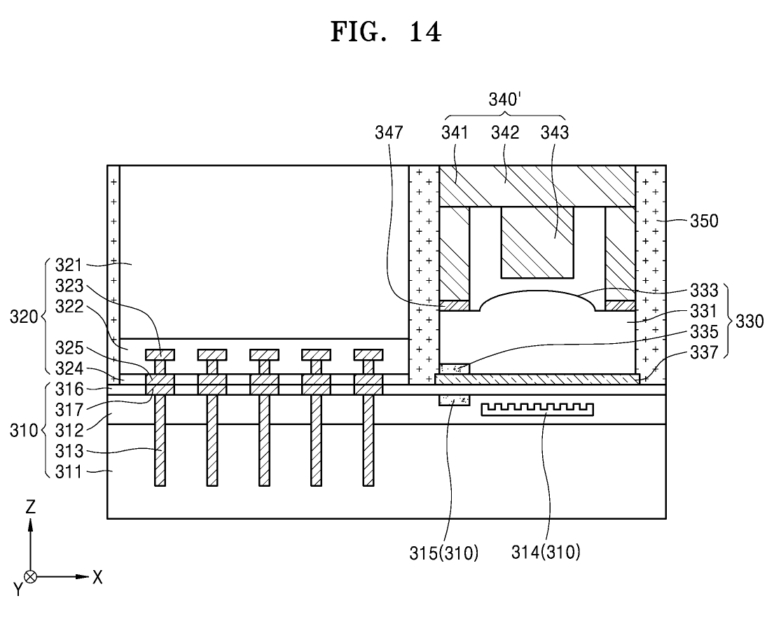

Referring to FIG. 14, a molding layer 350 may be attached to the photonics integrated circuit chip 310. The molding layer 350 may seal the electronic integrated circuit chip 320 and the optical block 330, on the photonics integrated circuit chip 310. The molding layer 350 may include, for example, thermocurable resin such as epoxy resin, thermoplastic resin such as polyimide, or resin including an inorganic filler, and in detail, may include ABF, FR-4, BT, or resin. Also, a molding material such as EMC or a photosensitive material such as PIE may be used.

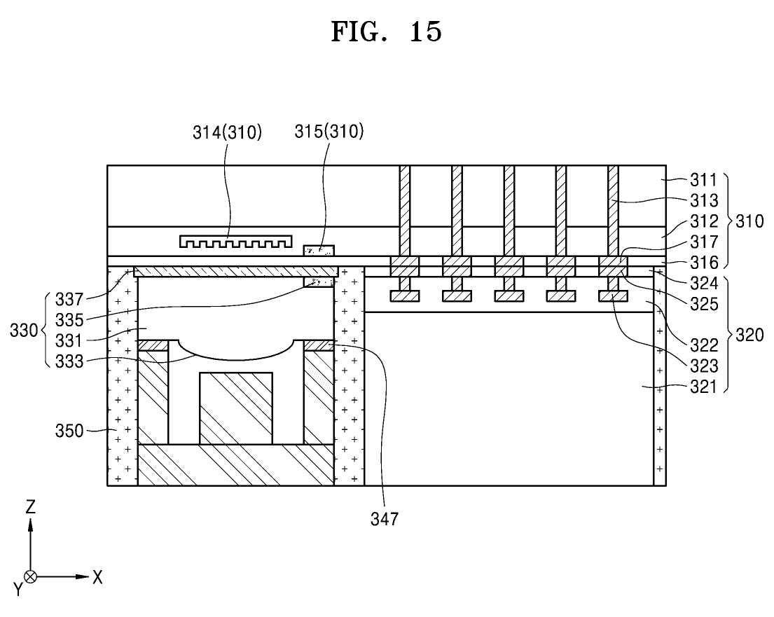

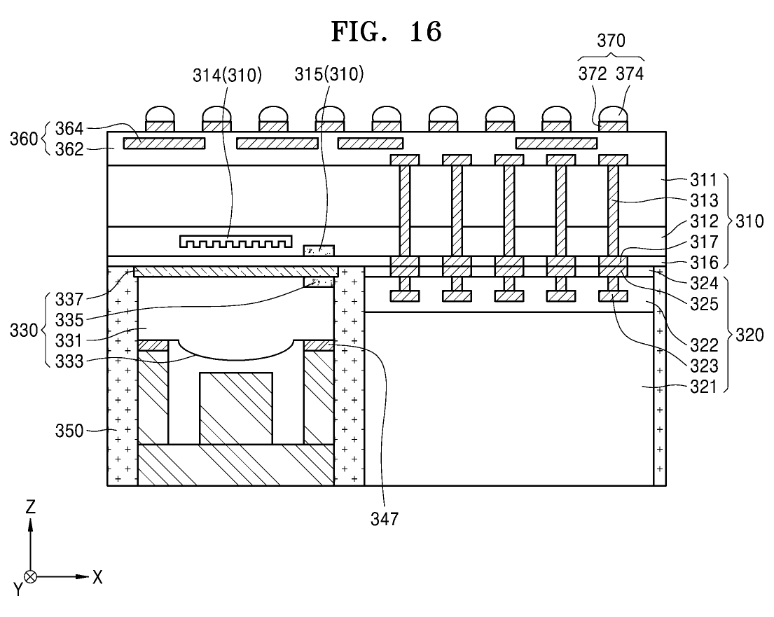

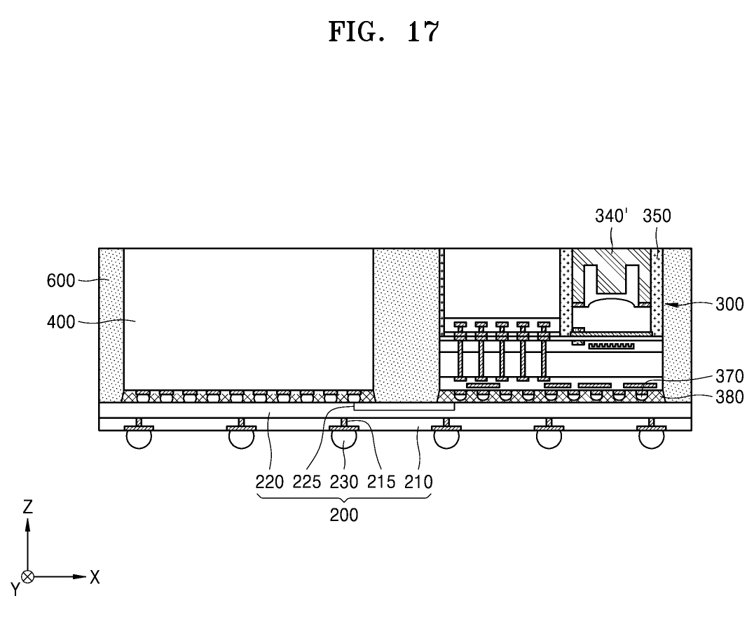

Referring to FIGS. 15 and 16, a first substrate 311 of the photonics integrated circuit chip 310 may be grinded in a state where the chip structure of FIG. 14 is reversed, and thus, a through via 313 may be exposed from the first substrate 311. A process of grinding the first substrate 311 may be a back grinding process and may be understood as a process of thinning the first substrate 311. When the through via 313 is exposed from the first substrate 311, a redistribution structure 360 may be formed on the first substrate 311. The redistribution structure 360 may include a redistribution insulating layer 362 and a redistribution pattern 364, and the redistribution pattern 364 may be connected to the through via 313 that is exposed. Subsequently, a connection terminal 370 may be formed on the redistribution structure 360.

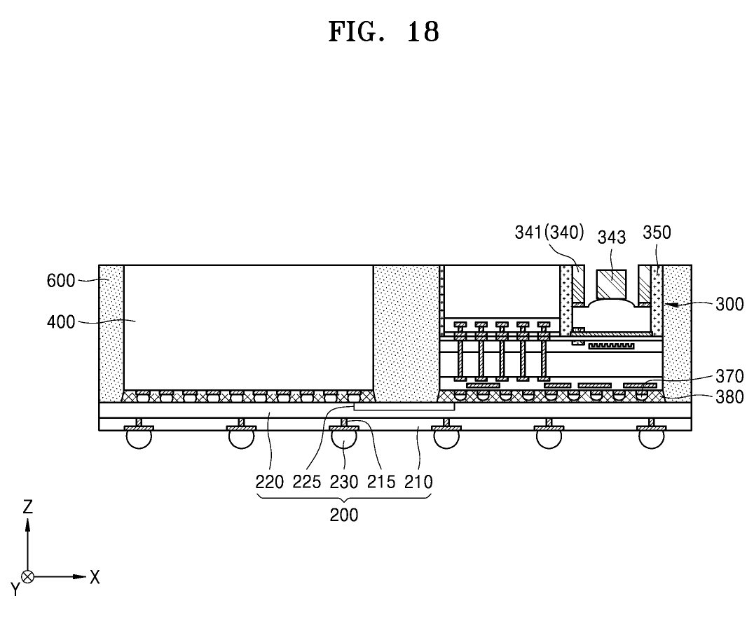

Referring to FIG. 17, the photonics chip structure 300 of FIG. 16, a first chip structure 400, and a second chip structure 500 may be mounted on a second package substrate 200. Subsequently, a package molding layer 600 may be formed on the second package substrate 200. The package molding layer 600 may cover the first chip structure 400, the second chip structure 500, and the photonics chip structure 300.

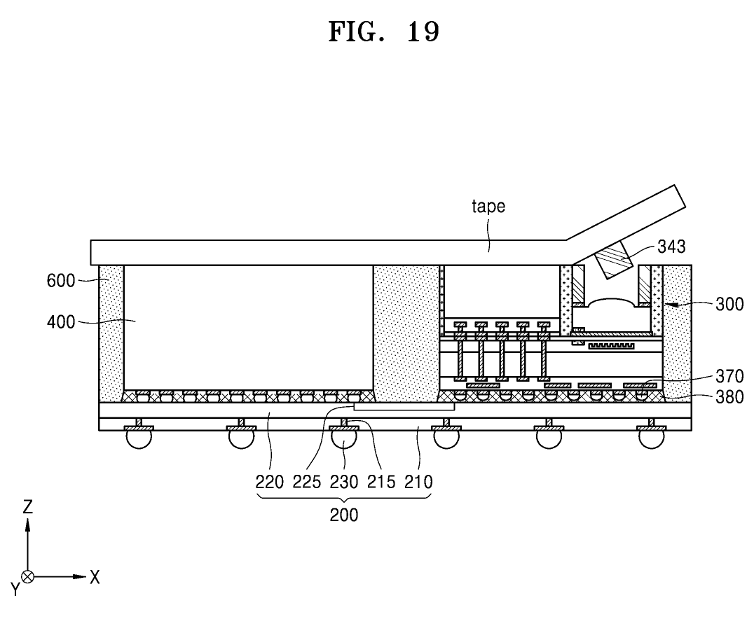

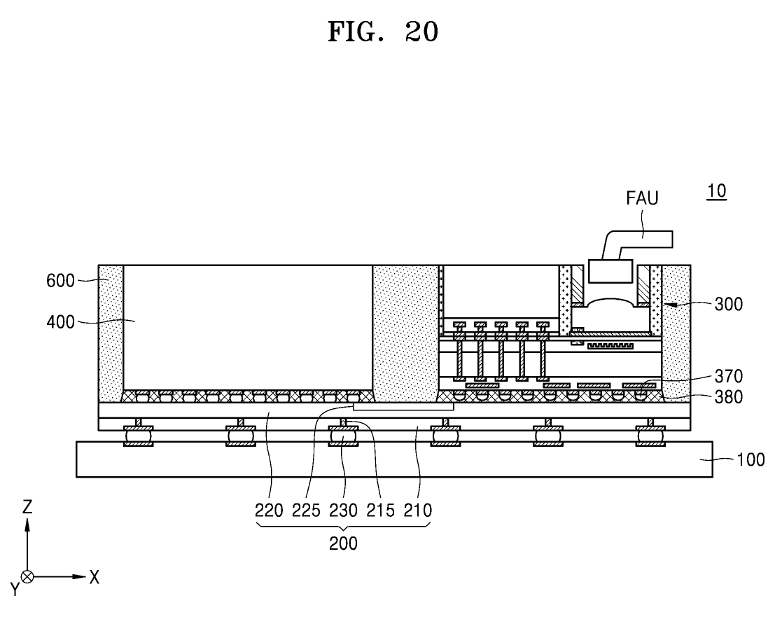

Referring to FIGS. 18 and 19, an appropriate thickness may be implemented by grinding an upper surface of each of the package molding layer 600, the first chip structure 400, the second chip structure 500, and the photonics chip structure 300. According to an embodiment, grinding may be performed to be greater than or equal to a thickness of the frame upper portion 342 of the primary frame 340’. As a result of grinding, the internal block 343 may be detached from the frame sidewall 341. The internal block 343, which is detached, may be removed through a peel-off process where a tape is attached to the upper surface of each of the package molding layer 600, the first chip structure 400, the second chip structure 500, and the photonics chip structure 300, and then, is detached therefrom. Subsequently, a process of cleaning a surface of the microlens 333 may be performed.

According to an embodiment of the present disclosure, a method of manufacturing a photonics chip structure may be provided and include: providing an electronic integrated circuit chip on a photonics integrated circuit chip; providing an optical block on the photonics integrated circuit chip, the optical block horizontally spaced apart from the electronic integrated circuit chip on the photonics integrated circuit; and providing a frame on an upper surface of the optical block, wherein the optical block includes at least one microlens, and the optical block is configured to provide a path of an optical signal of the photonics integrated circuit chip, and wherein the frame extends in a vertical direction on the upper surface of the optical block, and the frame is configured to protect the at least one microlens.

According to an embodiment of the present disclosure, the photonics integrated circuit chip includes a first alignment mark, and the optical block includes a second alignment mark, and wherein the providing the optical block includes aligning the first alignment mark and the second alignment mark.

According to an embodiment of the present disclosure, the second alignment mark is in a body part of the optical block, and a lower surface of the optical block and a lower surface of the second alignment mark are at a same vertical level as each other.

According to an embodiment of the present disclosure, the providing the electronic integrated circuit includes connecting the electronic integrated circuit to the photonics integrated circuit via a connection pad.

Referring to FIG. 20, the second package substrate 200 with the first chip structure 400, the second chip structure 500, and the photonics chip structure 300 mounted thereon may be attached to a first package substrate 100. Also, an optical fiber unit FAU may be disposed above the optical block 330, and thus, an external optical signal may be input to the optical block 330 through an optical fiber of the optical fiber unit FAU.

Non-limiting example embodiments have been described above with reference to the accompanying drawings. However, the present disclosure is not limited to the example embodiments. Those of ordinary skill in the art would appreciate that various modifications and other equivalent embodiments may be implemented, and the various modifications and equivalent embodiments are included within the spirit and scope of the present disclosure. It will be understood that various changes in form and details may be made to the example embodiments without departing from the spirit and scope of the present disclosure.

What is claimed is:

1. A photonics chip structure comprising:
a photonics integrated circuit chip;
an electronic integrated circuit chip on the photonics integrated circuit chip;
an optical block on the photonics integrated circuit chip, and horizontally spaced apart from the electronic integrated circuit chip, the optical block comprising at least one microlens, and the optical block configured to provide a path of an optical signal of the photonics integrated circuit chip; and
a frame on an upper surface of the optical block, the frame extending in a vertical direction on the upper surface of the optical block, and the frame configured to protect the at least one microlens.

2. The photonics chip structure of claim 1, wherein the photonics integrated circuit chip comprises a first alignment mark,
wherein the optical block comprises a second alignment mark, and
wherein the optical block is on the photonics integrated circuit chip so that the second alignment mark is aligned with the first alignment mark.

3. The photonics chip structure of claim 1, wherein the photonics integrated circuit chip comprises:
a first substrate;
a first interlayer insulating layer on the first substrate;
a first alignment mark on the first interlayer insulating layer; and
a through via passing through the first substrate and the first interlayer insulating layer,
wherein the optical block comprises a second alignment mark, and
wherein the optical block is on the first interlayer insulating layer of the photonics integrated circuit chip so that the second alignment mark vertically overlaps with the first alignment mark.

4. The photonics chip structure of claim 3, wherein the first alignment mark is in the first interlayer insulating layer and is at a same vertical level as a vertical level of an upper surface of the first interlayer insulating layer.

5. The photonics chip structure of claim 3, wherein the second alignment mark is in a body part of the optical block, and a lower surface of the optical block and a lower surface of the second alignment mark are at a same vertical level as each other.

6. The photonics chip structure of claim 1, wherein the at least one microlens comprises a plurality of microlenses that are arranged in at least one row at an upper portion of the optical block, and
wherein the frame is on the optical block, and the plurality of microlenses is in an internal space of the frame.

7. The photonics chip structure of claim 1, wherein the frame comprises frame sidewalls extending along an edge of the upper surface of the optical block,
wherein each of the frame sidewalls is connected to an adjacent one of the frame sidewalls, and
wherein a width of each of the frame sidewalls is 100 μm to 5,000 μm.

8. The photonics chip structure of claim 1, wherein the photonics integrated circuit chip comprises:
a first substrate;
a first interlayer insulating layer on the first substrate; and
a through via passing through the first substrate and the first interlayer insulating layer, and
wherein the first interlayer insulating layer comprises at least one grating coupler that is aligned with the at least one microlens of the optical block.

9. The photonics chip structure of claim 1, further comprising an optical fiber unit in an internal space of the frame, the optical fiber unit comprising a plurality of optical fibers, and the optical fiber unit configured to provide the optical signal to the optical block.

10. The photonics chip structure of claim 1, wherein an upper surface of the electronic integrated circuit chip is at a same vertical level as a vertical level of an upper surface of the frame.

11. The photonics chip structure of claim 1, wherein the frame is attached to the optical block via an adhesive layer.

12. The photonics chip structure of claim 1, wherein the optical block is attached to the photonics integrated circuit chip via an optical adhesive layer.

13. The photonics chip structure of claim 1, wherein a horizontal-direction width of the photonics integrated circuit chip is greater than a horizontal-direction width of the electronic integrated circuit chip.

14. The photonics chip structure of claim 1, further comprising a molding layer on the photonics integrated circuit chip and surrounding a side surface of the electronic integrated circuit chip, a side surface of the optical block, and an outer surface of the frame,
wherein an upper surface of the molding layer, an upper surface of the electronic integrated circuit chip, and an upper surface of the frame are at a same vertical level as each other, and
wherein the molding layer is not in an internal space of the frame.

15. A semiconductor package comprising:
a first package substrate;
a second package substrate on the first package substrate;
a semiconductor chip structure on the second package substrate; and
a photonics chip structure horizontally spaced apart from the semiconductor chip structure, on the second package substrate,
wherein the photonics chip structure comprises:
a photonics integrated circuit chip;
an electronic integrated circuit chip on the photonics integrated circuit chip;
an optical block on the photonics integrated circuit chip, and horizontally spaced apart from the electronic integrated circuit chip , the optical block comprising at least one microlens, and the optical block configured to provide a path of an optical signal of the photonics integrated circuit chip; and
a frame on the optical block, the frame extending in a vertical direction on an upper surface of the optical block along an edge of the optical block, and the frame configured to protect the at least one microlens.

16. The semiconductor package of claim 15, wherein the photonics integrated circuit chip comprises a first alignment mark,
wherein the optical block comprises a second alignment mark, and
wherein the optical block is on the photonics integrated circuit chip so that the second alignment mark is aligned with the first alignment mark.

17. The semiconductor package of claim 15, wherein the at least one microlens comprises a plurality of microlenses that are arranged in at least one row at an upper portion of the optical block,
wherein the frame comprises frame sidewalls extending along an edge of the upper surface of the optical block,
wherein each of the frame sidewalls is connected to an adjacent of the frame sidewalls, and
wherein the frame is on the optical block, and the plurality of microlenses is in an internal space of the frame, the internal space surrounded by the frame sidewalls.

18. The semiconductor package of claim 15, wherein the second package substrate comprises a silicon interposer or a redistribution substrate.

19. A semiconductor package comprising:
a photonics interposer comprising a grating coupler;
a semiconductor chip structure on the photonics interposer;
an electronic integrated circuit chip horizontally spaced apart from the semiconductor chip structure, on the photonics interposer;
an optical block on the photonics interposer, and horizontally spaced apart from the electronic integrated circuit chip , the optical block comprising a microlens, and the optical block configured to provide a path of an optical signal of the photonics interposer; and
a frame on the optical block, the frame extending in a vertical direction on an upper surface of the optical block along an edge of the optical block, and the frame configured to protect the microlens.

20. The semiconductor package of claim 19, wherein the photonics interposer comprises a first alignment mark,
wherein the optical block comprises a second alignment mark, and
wherein the optical block is disposed so that the second alignment mark is aligned with the first alignment mark, and the microlens and the grating coupler vertically overlap each other.
